(19) United States
(12) Patent Application Publication
(10) Pub. No.: US 2018/0042119 A1
(43) Pub. Date: Feb. 8, 2018

(54) STRUCTURE COMPRISING ELECTRICALLY SURFACE CONDUCTIVE LINES AND METHOD FOR MAKING ELECTRICALLY CONDUCTIVE LINES ON A SURFACE OF A STRUCTURE

(71) Applicants: AIRBUS GROUP, SAS, Blagnac (FR); MALLARD, Saint Antoine La Foret (FR)

(72) Inventors: Benoît DANTIN, Deuil La Barre (FR); Pascal LEMEILLE, La Trinite De Thouberville (FR)

(21) Appl. No.: 15/540,828

(22) PCT Filed: Dec. 30, 2015
(86) PCT No.: PCT/EP2015/081452

§ 371 Date: Jun. 29, 2017

(30) Foreign Application Priority Data
Dec. 30, 2014 (FR) 1463440

(51) Int. Cl. H05K 3/14; C23C 28/02; C23C 4/02; H05K 3/10; C23C 4/129; C23C 4/18; H05K 3/46; C23C 24/04; C23C 4/08

(52) U.S. Cl. CPC H05K 3/14; C23C 24/04; C23C 28/021; C23C 4/02; C23C 4/08; C23C 4/129; C23C 4/18; H05K 3/4685; H05K 3/102; H05K 1/056

(57) ABSTRACT

A structure including at least one electrical line on one surface of the structure, one electrically conductive layer of the line resulting from deposition of an electrically conductive material via a cold spraying method, and the line includes a protective bonding layer on which the electrically conductive material is deposited via the cold spraying method, the protective bonding layer forming a continuous protective shield between the structure and the cold-sprayed material. An insulating layer is advantageously located between the structure and the protective bonding layer. Achieving an electrical line on a surface of the structure involves implementing a step of oxy-fuel flame spraying of a protective material to form a protective bonding layer, followed by a step of cold spraying of the electrically conductive material of the electrically conductive layer onto the protective bonding layer.

### CROSS-REFERENCE TO RELATED APPLICATIONS

This application is the National Stage of International Application No. PCT/EP2015/081452, having an International Filing Date of 30 Dec. 2015, which designated the United States of America, and which International Application was published under PCT Article 21(2) as WO Publication No. 2016/107918 A1, and which claims priority from, and the benefit of, French Application No. 1463440, filed on 30 Dec. 2014, the disclosures of which are incorporated herein by reference in their entireties.

### BACKGROUND

### 1. Field

The disclosed embodiment belongs to the field of the structures incorporating items of electrical equipment and requiring the installation of electrically conductive lines.

Such a structure is, for example, that of a vehicle, for example the structure of an aircraft.

### 2. Brief Description of Related Developments

In the majority of structures, for example the structures of vehicles, there are currently installed items of equipment for which it is necessary to arrange electrically conductive lines, both in order to ensure a supply of electrical energy to each item of equipment and to transport signals in the electrical form from or toward the items of equipment.

One solution widely used, illustrated in FIG. 1, consists in attaching, to the structure 10, bundles 40 of electrically conductive wires connecting the different points which have to be brought into electrical connection, for example connecting an electrical energy distribution bar 42 with a supply terminal of an item of equipment 30 or connecting the inlets and outlets of two distant items of equipment which have to exchange information.

This solution, which functionally separates the structure and the electrical conductors, exhibits the disadvantage of employing wires requiring insulation, which is damaging to the weight of the electrical connections, and requires installing the wires on supports 41 or in sheaths in order to reduce the risk of damage to the insulator by wear in the event of rubbing over parts of the structure, which is again damaging to the weight and also to the available space delimited by the structure.

It is also known to have available conductor tracks on an insulating substrate in order to form electrical circuits, such as in the example of the method described in the document US 2011/0236566.

The method consists in producing a conductor track on an insulating substrate by the technique of the cold spraying of a conductive metal material.

However, this solution makes it possible to produce only relatively simple circuits, lines or loops, and requires that the substrate not be damaged by the cold spraying, which is mechanically aggressive. In practice, the solution provided can only be effectively used on hard and insulating materials, such as mineral glass.

It is also known to incorporate conductors in a structure made of composite material in the form of electrically conductive strips or wires which are incorporated in as many layers as needed in order to produce electrical supplies and the lines for the transportation of signals necessary for the different items of equipment.

However, such solutions prove to be complex to implement owing to the fact that they require that the definition of the electrical connections be fully established before producing the structure and owing to the fact that it is necessary to make provision for electrical links between the conductors incorporated into each piece of an assemblage in order to ensure the electrical continuity between the assembled pieces.

When electrical lines not provided during the preparation of the pieces have to be installed or when the assembled pieces exhibit defects of continuity of certain lines, the impossibility of adding lines incorporated in the structure results in the installation of wires added to the exterior of the structure, with the failings already mentioned.

In addition, the incorporation of conductive strips in a structure, for example between plies of a composite material, introduces disruptions into the structure which are capable of harming the mechanical performance levels of this structure. It is then necessary to provide, in a design, an over proportioning of the structural part in order to take into account this decrease in the performance levels.

Such a solution is thus not completely satisfactory, in particular in the case of large-size structures resulting from an assembling of several pieces.

It is also known, for example from the document US 2003/0219576, to produce printed circuit tracks made of relatively thick copper on an insulating substrate by carrying out cold spraying over an adhesion layer made of silver deposited by a printing technique. Such a solution is not suitable for the formation of conductor tracks on structures having complex shapes made of conductive materials or made of materials, the structural integrity of which absolutely has to be guaranteed on conclusion of a deposition by cold spraying, which in practice proves to be aggressive.

### SUMMARY

It is an object of the presently disclosed embodiment to overcome these disadvantages by simplifying the electrical installation in a structure, both in its design and in its implementation, and in the form of the installation obtained.

According to the disclosed embodiment, a structure comprises at least one electrical line on a face of said structure, an electrical conductive layer of said electrical line resulting from a deposition of an electrical conductive material, between ends of said line, on said face, by a cold spraying process.

The line additionally comprises a protective and tie layer resulting from a deposition of a material by oxy-gas flame spraying, on which layer is deposited an electrical conductive material by the cold spraying process, the material of said protective and tie layer being sprayed in order to form a continuous protective screen between the structure and the cold-sprayed material.

A high adhesion is thus obtained with a limited energy flux at the structure during the deposition of the material of said protective and tie layer, in particular by the choice of materials of the protective and tie layer not requiring a high spraying temperature and a high spraying energy, and the possibility to deposit the layer of the conductive material on the structure via the protective and tie layer, without the structure or another intermediate layer having been degraded by the highly energetic cold spraying of the conductive material.

In one aspect, in order to satisfy the mechanical requirements of the protective and tie layer and the constraints of a deposition by oxy-gas flame spraying, the protective and tie layer comprises mainly zinc, or a zinc-based alloy, or aluminum, or an aluminum-based alloy.

In one aspect, the protective and tie layer exhibits a thickness of between 0.05 mm and 1.5 mm. A thickness within this interval is generally sufficient as protective layer in the present application and limits the energy necessary for the formation of the protective and tie layer by the flame spraying process, which energy is capable of degrading the support of said protective and tie layer.

In one aspect, an insulating layer of an electrical insulating material is interposed between the structure and the protective and tie layer, a width of the insulating layer being greater than a width of the protective and tie layer.

Electrical insulation between the line and the structure and protection of the structure during the operations for deposition of the protective and tie layer and of the conductive layer are thus ensured.

For example, the insulating layer comprises at least one ply of glass fibers or of fibers of an electrically insulating polymer held in a cured matrix of an organic polymer.

A thickness Eᵢ of the insulating layer is between 0.2 mm and 1 mm. Sufficient electrical insulation for ordinary voltages of an electrical network generally employed in a structure when this electrical insulation is desired and without the penalty of excessive weight is thus obtained.

According to one aspect, in order to obtain electrical conduction performance levels desired, the electrical conductive layer mainly comprises copper, or a copper alloy.

According to one implementational alternative, the electrical conductive layer mainly comprises aluminum, or an aluminum-based alloy, which, while being lighter than copper, exhibits good electrical conduction characteristics.

In one aspect, the electrical line comprises means for electrical connection to items of equipment so as to simply ensure the linking of the line to the items of equipment which have to be connected.

In one aspect, the structure comprises a plurality of electrical lines, in accordance with the line in the structure of the disclosed embodiment, in which at least one upper line crosses at least one lover line, said at least one lower line being locally between the structure and said at least one upper line, said at least one upper line comprising an insulating layer at least where the lines intersect.

It is thus possible to produce complex networks comprising a plurality of lines on the structure and within which network the lines can intersect without particular disadvantage.

In the disclosed embodiment, the structure is made of a metal material and/or of a composite material comprising organic or inorganic fibers held in a cured organic matrix.

The disclosed embodiment also relates to a process for producing an electrical line on a surface of a face of a structure, said process comprising the formation of an electrical conductive layer, of the electrical line, resulting from a deposition by a cold spraying process of an electrical conductive material, between ends of the line, on the face of the structure.

The process additionally comprises a stage of oxy-gas flame spraying of a protective material in order to form a protective and tie layer, followed by a stage of cold spraying of the electrical conductive material of the conductive layer on said protective and tie layer.

There is thus formed, by a flame spraying process which is relatively not very aggressive for the structure or for lower layers, the protective and tie layer on which can be deposited the conductive layer and which protects the lower layers from the mechanical effects of the cold spraying of the conductive material.

In one aspect, the process additionally comprises a stage of deposition, on the structure, of an electrical insulating layer on which is produced the protective and tie layer by oxy-gas flame spraying of the protective material.

The insulating layer makes it possible to ensure electrical insulation of the line produced in the case of electrical conductive structures, such as metal structures or such as composite structures comprising carbon fibers, which are not sufficiently insulating to avoid the use of an insulating layer. The insulating layer also makes it possible to protect the structure during the implementation of the processes for deposition by flame spraying and for deposition by cold spraying of the upper layers. The insulating layer also makes it possible to deposit the track on a homogeneous support even in the case of changes in materials of the structure and thus makes possible better control of the processes for deposition of the upper layers.

In one aspect, the insulating layer is made of at least one ply of a fabric of glass fibers or of fibers of an electrically insulating polymer which are held in a matrix of an organic polymer and attached to the structure.

In one aspect, the material sprayed by the oxy-gas flame spraying process in order to form the protective and tie layer mainly comprises zinc, or a zinc-based alloy, or aluminum, or an aluminum-based alloy.

Advantageously, the protective and tie layer is formed with a thickness of between 0.05 mm and 1.5 mm.

In one aspect, during the stage of producing the protective and tie layer, the temperature of the flame is between 200° C. and 3000° C., advantageously between 280° C. and 1100° C., a rate of spraying of the material being between 20 m/s and 100 m/s, preferably between 25 m/s and 70 m/s.

In one aspect, the material cold-sprayed in order to form the electrical conductive layer mainly comprises copper, or a copper-based alloy.

In one aspect, the material cold-sprayed in order to form the electrical conductive layer comprises mainly aluminum or an aluminum-based alloy.

In one aspect, the cold spraying of the sprayed material is carried out with temperatures of the gas employed of between 100° C. and 1100° C., preferably of between 200° C. and 600° C., and with pressures of said gas of between 10 times and 50 times standard atmospheric pressure, preferably with pressures of between 18 times and 45 times standard atmospheric pressure.

### BRIEF DESCRIPTION OF THE DRAWINGS

The disclosed embodiment is described in detail with reference to the drawings which diagrammatically represent:

FIG. 1 (already cited) is an example of a structure comprising a conventional electrical installation with electrical cables and cable supports;

FIG. 2 illustrates an example of electrical installation according to the disclosed embodiment for a structure similar to the structure of FIG. 1;

FIG. 3 is a view in perspective and in section of a simple example of line according to the disclosed embodiment, the line being represented in the simple case by a rectilinear line on a flat structure;

FIG. 4a is a simplified representation in section of an example of electrical lugs added to the conductive layer of a track, an example of soldered lug and an example of clamped lug;

FIG. 4b is a representation in perspective view of a line in an example of junction region of two pieces of a structure;

FIG. 4c is a representation in section of a crossing of two lines on a face of the structure;

FIGS. 4d and 4e are representations of examples of passive components produced on a face of the structure following the principles of producing a line, where FIG. 4d is an example of resistors combined in parallel and FIG. 4e is an example of inductor;

FIG. 4f is a simplified representation in section of a defect of the conductive layer of the line repaired by a shunt soldered to the layer or produced by cold spraying with a conductive material; and

FIG. 5 is a block diagram representation of the main stages of the process of the disclosed embodiment.

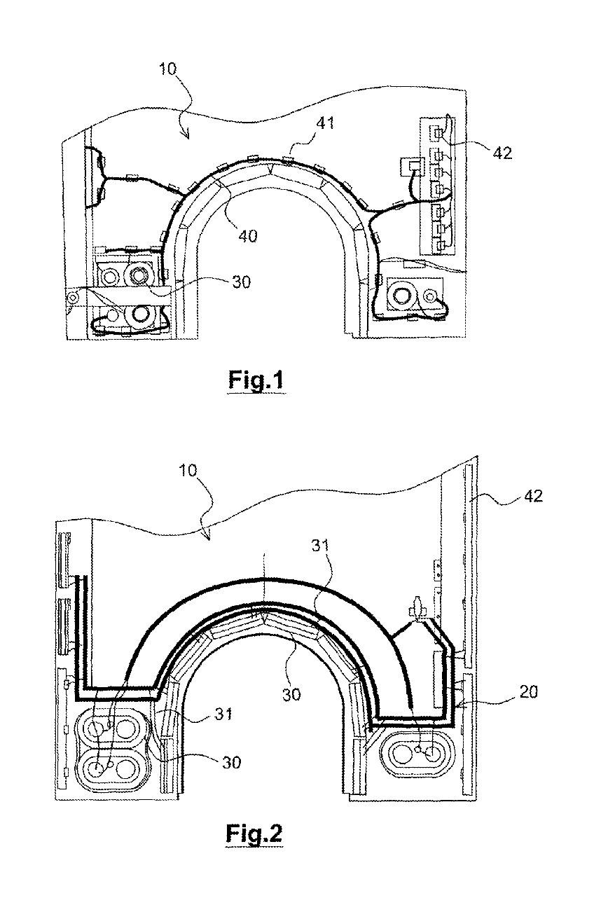

The figures are diagrammatic representations of principles. In these figures, the different parts are not necessarily represented at the same scale, the understanding of the disclosed embodiment being favored rather than the realism of the illustrations.

In the figures, elements similar in their structures or their functions are marked out by one and the same number even if they exhibit different forms.

For simplicity, the conductive lines are represented as rectilinear and on surfaces of flat structure. The disclosed embodiment is not limited to this aspect and the conductive lines can follow any trajectory, curved and/or angular, at the surface of non flat structures which can exhibit surfaces curved in space and which can exhibit complex shapes resulting from assembling of pieces.

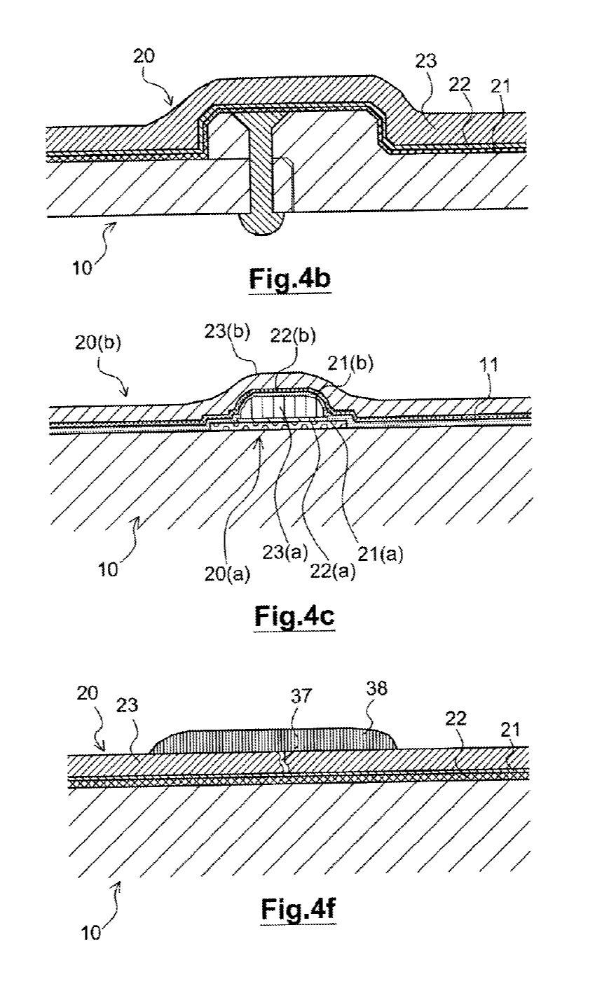

Although the piece can exhibit any orientation in space, orders and orientations corresponding to those of FIG. 3 will be considered in the description.

Thus, in the description, the structure 10 is regarded as a lower element and, in a stack of elements produced on a surface 11 of said structure, a layer formed on another layer is more distant from the surface of the structure than this other layer and, on the contrary, it is closer to the surface of the structure if it is located under the other layer, whatever the orientation of the piece in space.

FIG. 3 shows, in perspective view, a part of a structural piece on which is formed an electrical conductive element producing electrical connections between connection means 25.

For simplicity, an electrical conductive element according to the disclosed embodiment will be denoted by the term “line” 20 in the continuation of the account, and the terms “conductive” and “insulating”, unless otherwise indicated or there is evidence to the contrary, will be relative to the electrical conduction as regarded in the field of the applications in the transportation of electrical currents for supplying with energy or for the transmission of signals.

In FIG. 3, the line 20 is shown in perspective view, in section, so that the different constituents elements of the line are visible following the arrangement which they have in said line of the disclosed embodiment.

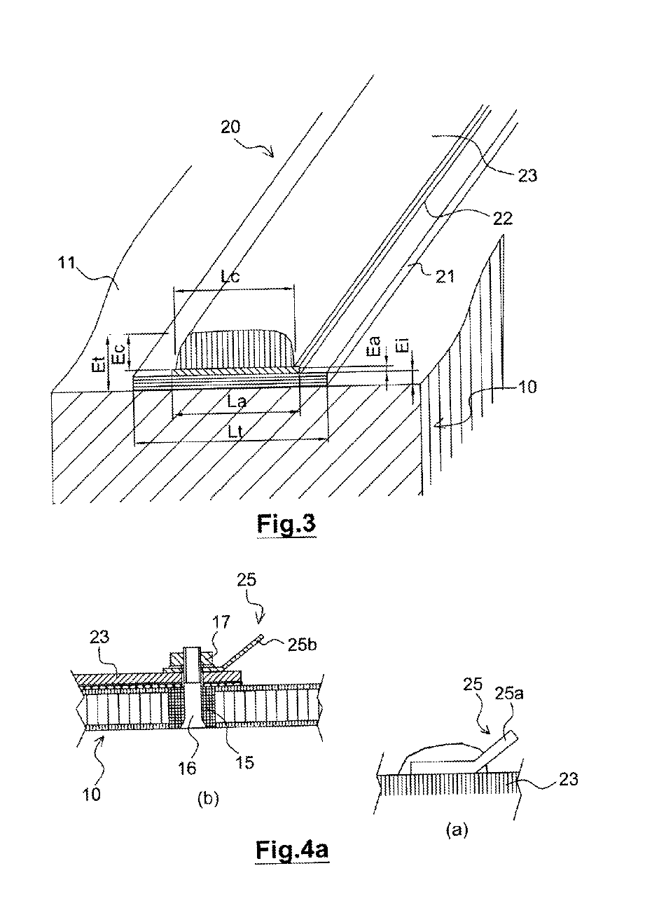

In the example of FIG. 2, the structure 10 supporting the line 20 is a structure belonging to a structural part of a vehicle, not represented. Said structure can be made in all or in part of a material exhibiting a low resistivity, as is the case with the majority of metals, for example aluminum alloys, steels, copper alloys and the like.

It can also be made in all or in part of a material exhibiting a relatively high resistivity without coming within the category of insulating materials, such as, for example, a composite material with carbon fibers.

It can also be made in all or in part of an insulating material, such as, for example, a composite material comprising organic fibers, for example aramid fibers, or glass fibers, in an insulating polymer matrix.

### DETAILED DESCRIPTION

In the present application, the materials regarded, in the sense understood for an electrical installation, as conductors are generally those having a resistivity of less than 10⁻⁷ Ω·m and those regarded as insulators are generally those exhibiting a resistivity of greater than 10¹⁰ Ω·m, the materials between these two values generally being regarded as weakly conductive.

By way of illustration, carbon fibers, regarded as weakly conductive, have electrical resistivities generally of between 1.5×10⁻⁶ Ω·m and 1.5×10⁻⁵ Ω·m.

The line 20 of FIG. 2 exhibits a total width Lt and a total thickness Et.

In the example illustrated, the line comprises three superimposed layers: a first insulating layer 21 deposited in contact with the surface 11 of the piece, a second protective and tie layer 22 formed on the first layer, and a third conductive layer 23 formed on the protective and tie layer.

The line 20 is thus formed by superimposed strips corresponding to the different layers, said strips following a route of the line over an entire length of said line.

The first insulating layer 21 consists of an insulating material exhibiting mechanical properties which allow it to accompany the deformations of the structure 10 in service without being damaged, in particular without breaking and without detachment of said first insulating layer.

In one aspect, the first layer 21 is formed mainly with one or more plies of glass fibers impregnated with a polymerized resin, which resin is chosen as a function of the material of the piece in order to ensure perfect adhesion, with or without the use of an intercalated adhesive. Resins which ensure good adhesion, for example, to aluminum alloys, for example epoxy resins, are known. When the piece 10 is formed of a composite material comprising organic or inorganic fibers, held in a resin, the resin employed for the glass plies of the first layer 21 is advantageously a resin which is compatible with the resin of the piece and which can adhere during a polymerization in contact with said piece.

As will be understood from the continuation of the description and the implementation of the production process, the first insulating layer 21 is made of a material resistant to a deposition of material by “oxy-gas” flame spraying.

Such a deposition process is known and relatively old.

It exhibits the property of being able to be carried out with relatively low kinetic energies owing to the fact that the material introduced is deposited in a liquid phase, or at least in a pasty state, as a result of the heating thereof in the flame.

It thus makes possible good attaching of the deposited material and, as explained subsequently, subject to choice of suitable parameters of the process, makes it possible not to damage the substrate formed by the first insulating layer 21 and by the material of the structure 10.

The first insulating layer 21 is, for example, added to the surface 11 of the piece 10 by adhesive bonding.

In the case of a piece made of composite material which has to constitute the structure or which has to participate in an assemblage of the structure, said first layer can be the result of an adhesion process during the manufacture of the piece, for example by cocuring of the resins of the piece and of the first insulating layer 21.

The first insulating layer 21 does not here have the calling of reinforcing the structure of the piece, although this possibility can be taken into account in the design of the structure, and, by definition as a result of its insulating nature, does not participate in the electrical conduction of the line 20.

A thickness Ei of the first insulating layer 21 will thus be chosen to be as thin as possible, in order to minimize the penalty of weight thereof in particular.

However, the thickness Ei will be sufficient to contribute, to the support formed by the first insulating layer 21, the expected mechanical strength and to ensure the desired electrical insulation, taking into account the possible imperfections of its preparation, in particular on consideration of the differences in electrical potential between the electrically conductive part of the line and the structure when the latter is conductive or is not regarded as sufficiently insulating, so as to prevent electrical breakdowns in use.

In the context of an application to a structure of a vehicle, for example an aircraft, the thickness Ei of the first insulating layer 21 is advantageously between 0.2 mm and 1 mm.

In the implementational example of FIG. 3, the first insulating layer forms an insulating strip, the width of which corresponds to the total width Lt of the line 20.

The second protective and tie layer 22, deposited on the first insulating layer 21, has the role of making possible attachment of the third conductive layer 23 and also of forming protection of the lower layers during the operations for deposition of a conductive material forming said third conductive layer.

The second protective and tie layer 22 is in this instance a layer comprising mainly zinc or aluminum, pure or alloyed, which is deposited by flame spraying, with a low thickness Ea of between 0.05 mm and 1.5 mm.

The second protective and tie layer 22 exhibits a width La which is less than the width Lt and which is advantageously more or less centered on the strip formed by the first insulating layer 21, so that said second protective and tie layer is not in direct contact with the structure 10, in particular in the case of a structure produced with noninsulating materials.

The material forming the second protective and tie layer 22 is deposited in order to form a continuous strip by a process for the deposition of material by oxy-gas flame spraying.

In the present case, the parameters for the application of the process for flame deposition, in particular: material deposited, temperature, rate of spraying, are chosen in order to form the second protective and tie layer 22 without damaging the first insulating layer 21 and without damaging the material of the structure 10, as will be specified in the process of the disclosed embodiment.

The third conductive layer 23 is a metal layer comprising mainly copper or a copper-based alloy, or aluminum or an aluminum-based alloy.

Other electrical conductive materials, pure or in the form of alloys, can be used to form the third conductive layer, provided that it can be deposited as described in the process with an energy at the surface on which the material of said third layer is deposited without damaging the lower layers.

The third conductive layer 23 ensures, in the line 20, the passage of the electrical current with the desired intensity.

The conductive material used to form the third conductive layer is deposited following a cold spraying process.

In the case of the disclosed embodiment, the cold spraying process, known per se, is advantageously carried out, in order to obtain the desired mechanical and electrical performance levels of the third layer, with a minimum energy in order to avoid damaging the lower layers of the line 20 and the material of the structure 10.

The cold spraying process exhibits, in the case of the presently disclosed embodiment, several advantages for the production of a deposit of the conductive material in order to form a line.

In particular, the third layer 23 can be produced with very different widths and thicknesses and thus makes it possible to form lines in order to result, in a broad range of intensities of the currents.

In practice, a thickness Ec and a width Lc of said third layer determine a conductive section of the line which is a function of a maximum intensity of the electrical current which has to be conducted by the line 20 and also of the resistivity of the conductive material used and of its length, in order to take into account the losses of potential as in any electrical installation.

The third conductive layer 23 is substantially superimposed on the second protective and tie layer 22, with which second protective and tie layer it preferably exhibits an equal or slightly lower width in order to benefit from a maximum attaching surface area.

Depending on the needs for change in intensity of the electrical current, a thickness Ec of the third conductive layer is between approximately a tenth of a millimeter and several millimeters, in practice up to at least 10 millimeters for everyday applications.

For example, when the line is intended to conduct low currents, as in the case of the transmission of analog or digital electrical signals, a conventional wire of gauge 30 according to the AWG standardization, with a conductive section of 0.05 mm², is advantageously replaced by a line with a third conductive layer with a width of 0.5 mm and a thickness of 0.1 mm, which makes it possible to produce the process of the disclosed embodiment.

On the other hand, when the line is intended to transport high currents, for example corresponding to the use of conventional wires of gauge 10 or less according to the AWG standardization, corresponding to sections of 5 mm² or more, the line will advantageously be formed with thicknesses of the third conductive layer which can reach or exceed 8 mm with widths, for example, of between 1 mm and widths unlimited in theory.

For example, a line with a conductive section of 80 mm² with a width of 10 mm and a thickness of 8 mm, that is to say substantially a gauge 3/0 according to the AWG standardization, is in a position to supply items of equipment which are high consumers of current, such as electric power actuators.

A conductive width of the line, in that it is determined by the width Lc of the third conductive layer, is not constrained by the principles of the disclosed embodiment and can thus be highly variable according to the installation requirements of the line under consideration.

In practice, the designer will determine, according to his electrical installation constraints, in particular the dimensions of the structure and a number of lines which have to pass on the surface 11 of the structure, for each line a ratio which he will give between the conductive width Lc and the conductive thickness Ec in order to obtain the conductive section desired for the line.

It should be noted here that, for a given conductive section, this ratio is not necessarily constant over an entire length of the line 20, in particular in order to meet installation constraints of the lines.

In the example of a line according to the disclosed embodiment which has just been described, the case of an isolated line is considered.

In the majority of cases of a complex electrical installation, generally several lines will be formed on the surface 11 of the structure 10, as in the example of FIG. 2. In this case, one and the same first insulating layer can be produced in order to support several second protective and tie layers and third conductive layers, advantageously in the case of lines close to one another. In such an aspect, the line width Lt considered in the description will advantageously be interpreted as the width taking into account a width of the first insulating layer 21 allocated to a line under consideration.

In this case, the first insulating layer necessarily has a width sufficient to deposit the other layers of lines without risk of interference between the second and third layers of the different lines.

In a specific embodiment, an insulating layer is deposited over the entire surface of the piece so that the second and third layers can be deposited without constraint with regard to the question of the electrical insulation with respect to the structure.

In the latter case, the deposition of a complementary first insulating layer may prove to be necessary in regions of junctions of pieces of the structure as a result of assemblages which are not necessarily protected by the insulating layer attached to the surface of pieces during their preparation and before assembling to form the structure.

In one aspect, the structure is made of an electrically insulating material and the line of the disclosed embodiment is formed without the first insulating layer, the function of which is then provided by the structure itself.

However, even in the case of a structure made of an insulating material, it may be preferred to employ a first insulating layer 21 which will ensure protection of the structure during the production of the second and third layers of the line at the time of the production of said line and which will also ensure functions of protecting the structure in the event of intervention in order to repair the line 20, indeed even to remove from the surface 11 of the structure, for example by abrasion or machining, all or a part of the line in the case of a repair or of a modification of the definition of the electrical installation.

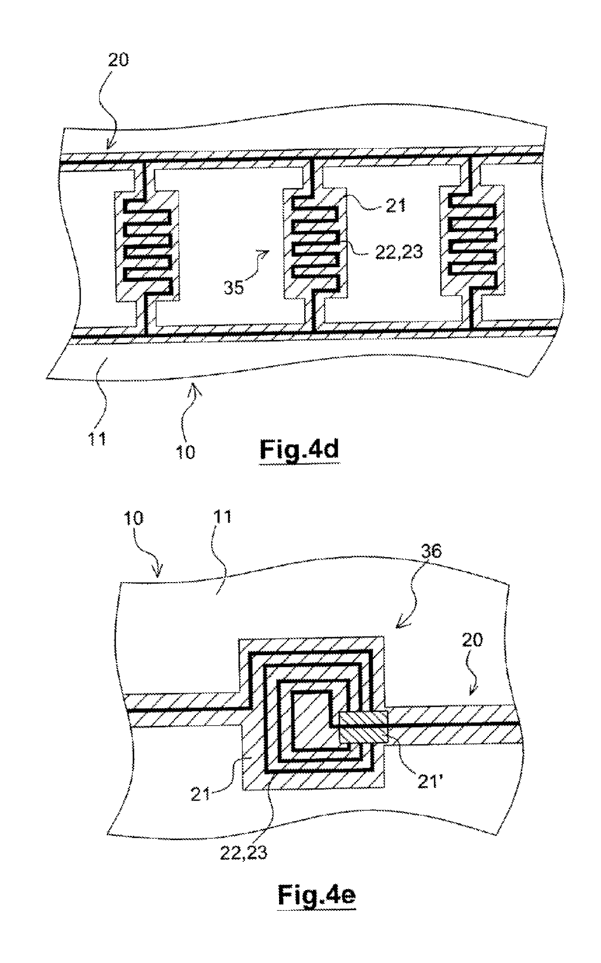

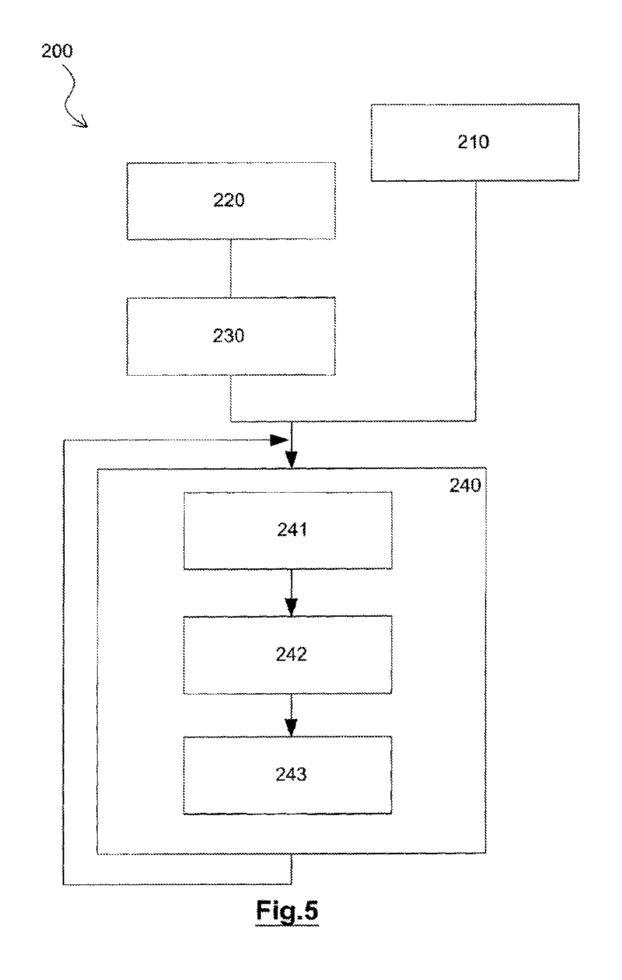

It should also be understood that the disclosed embodiment makes it possible to produce lines which intersect on the face 11 of the piece. A crossing is rendered possible by the first insulating layer which is deposited on top of a line already formed before depositing the other layers of another line crossing the line already formed and makes it possible to ensure the electrical insulation between the two lines distinguished in the illustration of FIG. 4c by the indices (a) and (b).

It is thus understood here that complex electrical installations comprising a plurality of lines can be arranged on a face of a structure, provided that said face is accessible in order to make it possible to form said lines with the means employed.

In one aspect, an insulator, advantageously in the form of a resin or a paint, is deposited on the lines 20 produced in order to create an electrically insulating layer ensuring both protection of people who may be brought into contact with conductive parts of the lines and ensuring protection against short circuits in the case of contact of the structure with conductive objects and also ensuring protection of the conductive materials of the lines with regards to external attack, in particular oxidation and other potential chemical attacks.

In a preferred form, this protective layer is transparent, so that defects, for example a breach of the third conductive layer 23, can be detected or looked for visually.

The use of a protective layer transparent to infrared radiation also makes it possible to detect, on carrying out an examination using a thermal camera, a defect in conduction which in many cases is reflected by local overheating due to an increased electrical resistance at the location of the defect.

Such an inspection can also be carried out in the context of control of the quality of the lines during the manufacture of said lines and of the structure in order to supplement the tests of continuity and of insulation generally carried out on conventional electrical installations.

In one aspect, as illustrated in the examples in FIG. 4a, a line 20 comprises connection means 25, for example lugs 25a, 25b or electrical terminals, attached to the third conductive layer 23, for example by soldering, as in the breakdown (a) of FIG. 4a, when the line is produced or by incorporation in the third layer 23 during the production of said third layer, ensuring the electrical continuity between said third conductive layer and each connection element.

Such connection means 25 are arranged at any point of the line 20 where it is intended to join, by a conventional electrical line 31, an item of electrical equipment 30 or in order to ensure electrical continuity with a part of the electrical installation either in accordance with the disclosed embodiment but, on another structural part, or produced according to a conventional architecture. It should be noted that supernumerary connection means may be available on a line 20 in stock, for example for the installation of new items of equipment or in order to respond to repair solutions.

Connection means 25 can be attached to an end of line 20 or in any location between ends of said line.

In practice, the connection means can be attached by any arrangement making possible a join ensuring electrical continuity.

Connection means can consist of a lug held on the third conductive layer 23 by soldering or by incorporation in the third layer, as already specified.

Connection means can also consist of joining means, such as an assembly of electrical terminals, which is, for example, attached to the structure while maintaining the necessary electrical contact with the third conductive layer 23, which case is not illustrated.

Connection means can also consist, as illustrated in the breakdown (b) of FIG. 4a, of a hole made in the structure 10 and passing through the third conductive layer 23 so that there can be placed a screw 16 for clamping, with a nut 17, against said third conductive layer, a ring lug 25b, a terminating element of a conventional electrical conductor. In this case, advantageously, the third layer 23 exhibits a sufficient surface area, if need be by a form which is locally widened with respect to the current conductive width Lc, in order to form a supporting surface for the clamped lug.

In the case of a structure 10 made of composite material, it will be possible to consider placing, in said composite structure, at the location planned for a connection, an insert 15 comprising the hole receiving the screw 16 for the clamping of the lug 25b, whether the hole of the insert is a threaded hole for receiving the clamping screw of the lug, or whether the insert forms, as presented in the breakdown (b) of FIG. 4a in the case of a structure of sandwich type having a cellular core, a traversing hole which avoids piercing the composite structure and which avoids carrying out direct clamping on the composite structure.

Such an insert can be made of a conductive material and there will, in this case, be deposited different layers of the line in order to guarantee electrical continuity between the insert and the third conductive layer.

In one aspect, such a conductive insert, when it passes through the structure, ensures an electrical connection between opposite faces of said structure.

Although electrical lines for the transportation of currents, of powers or of signals are considered above, the second and third layers can correspond to more or less complex patterns for forming, on a line or an assembly of lines, passive electrical components, for example inductors 36, radiating elements or resistors 35, as illustrated in the breakdowns of FIGS. 4d and 4e, and generally any type of passive component capable of being produced by conductive surfaces or lines.

FIG. 4d illustrates an example of resistors 35, mounted in parallel in the example, which can be used as heating means, for example for producing de-icing functions of a structure.

FIG. 4e illustrates an example of inductor 36 produced in the form of a flat coil.

In these two examples, the components are produced by means of lines 20 in accordance with the disclosed embodiment and exhibiting the characteristics suited to the application under consideration, in particular of electrical resistance as regards the resistors and of geometry as regards the inductors.

In the implementation examples of components illustrated in FIGS. 4d and 4e, the first insulating layer 21 is produced in the form of a surface covered with the substantially rectangular structure in order to support the second and third layers forming the component. When the pattern produced by the conductive layers results locally in an undesired superimposition of deposition of conductive material, there is, as in the example illustrated in FIG. 4e, deposited a first insulating layer 21′.

These possibilities make it possible to produce, for example, radioelectric antennae, various sensors, heating elements for de-icing systems directly incorporated on a face of the structure.

The disclosed embodiment also relates to a process 200 for producing a structure 10 comprising one or more electrically conductive lines 20 deposited on a face 11 of said structure in order to form electrical connections between connection means 25 tor joining items of equipment 30 and/or electrical conductive wires 31.

According to a preferred aspect, in a first stage 210, a structure 10 or a structural part, for example a structure of a vehicle, is produced conventionally, at least in the case of a complex structure like that of a vehicle, such as an aircraft, by an assembling of individual pieces.

An individual piece can consist of any material or assemblage of materials which are electrically insulating and/or electrically conductive, said piece being designed in order to meet as a priority the structural requirements of the structure in which it is incorporated.

A piece can be mainly of metal, for example made of an aluminum-based alloy, made of a steel, made of a titanium-based alloy, and the like.

A piece may also be mainly made of composite material, for example comprising inorganic or organic fibers held in a polymer matrix.

In a second stage 220, associated with the design of the vehicle, there is defined, on at least one face 11 of the structure 10, or of the structural part, the position of the connection means 25 which have to be electrically linked by a conductive line 20 and, associated with said connection means, the electrical performance levels, mainly the electrical currents conducted and the electrical voltages applied, which have to be considered.

A person skilled in the art understands here that, by current and voltage, he has to take into account, as in the design of any electrical installation, the different conditions liable to result in a specific proportioning of an electrical line, for example the continuous maximum or nominal values, the short circuit values, and the like.

In a third stage 230, there is defined a course, on the face or faces 11 of the structure 10, for each line 20 linking locations of the different connection means 25 of the line under consideration.

In this third stage, conventional methods for designing electrical installations will be employed while adding thereto the constraint that the lines 20 are formed on the face of the structure which, in the most general case, forms a nonplanar surface.

This constraint results in there being taken into account, on the one hand, that the installation is mainly two-dimensional, whereas, in a conventional design, it is possible to exploit a third dimension of the space by more or less moving the lines away from the structure and, on the other hand, possible discontinuities of the structure which can result in routes of lines being diverted for reasons of facilitating production or repair of a line, or to avoid risks of damage of a line in operation.

It should be considered therefore that the production of a line 20 employs more or less bulky and ponderous means and that the lines have to be formed with an accuracy generally in the order of a millimeter, indeed even less, and that the person skilled in the art has to take into account the use of these means in the structure under consideration.

In this third stage, there are also defined the geometrical characteristics of the line which take into account the expected electrical performance levels and the installation constraints.

Thus, there is determined a total width Lt of the line 20, a width Lc of a conductive strip of the line and a thickness Ec of said conductive strip.

The width Lc and thickness Ec pair of the conductive strip is chosen in order to obtain the desired surface area of the electrically conductive section.

The total width Lt of the line, which corresponds to that of an insulating support of the conductive part of the line 20, results from the choice of the width Lc of the conductive strip and from the need for said conductive strip not to laterally extend beyond said insulating support. Advantageously, Lt is greater than Lc by a minimum of one millimeter.

It should be pointed out that the total width Lt, the width of the conductive strip Lc and the thickness of the conductive strip Ec are not necessarily constant and can be different according to a location under consideration of a length of the line 20.

These widths and thicknesses, which correspond to transverse dimensions of the line 20, can change, for example, at a constant performance level, as a function of local geometric constraints imposed by the structure 10, and/or as a function of variable performance level requirements when a line 20 is used, for example, to supply several items of equipment distributed along said line and when, consequently, the maximum current in the line decreases as a function of the number of items of equipment remaining downstream of a point under consideration of said line.

When the different data necessary for producing a line 20 are established, said line is produced in a fourth stage 240, on the surface corresponding to the face 11 of the structure 10 on which the line has to be formed, by the successive deposition of three superimposed layers.

In a first substage 241 of this fourth stage, a first insulating layer 21 is deposited on the structure.

Said insulating layer is provided, for example, in the form of a strip with a width Lt which adheres to the surface of the face 11 while following the course defined for the line 20 on said surface.

Besides this characteristic of electrical insulator, the material employed to form the insulating layer 21 has to be able to be attached to the structure, with a hold which makes it possible to guarantee the quality of the adhesion under the environmental conditions, and for at least the duration of use, of the structure. It also has to be compatible with the material of the structure.

Furthermore, it has to make possible the use of the process for depositing the second protective and tie layer 22 which has to support the third conductive layer 23 and also has to withstand the conditions imposed by the process for deposition of said third layer, the conditions of which are described in detail below.

When the material of the structure is compatible, the first insulating layer 21 can be made of a ceramic material.

In an advantageous form, the first insulating layer 21 is formed by depositing a strip formed of one or more plies of glass fibers or of polymer fibers impregnated with a polymer matrix and maintained by adhesive bonding.

The deposition can be carried out by any known process for supplying a layer of a composite material to a structure consisting, if appropriate, of a structure in the course of preparation. Advantageously the strip is deposited by a robot which applies said strip in the form of a strip unwound along the desired trajectory by applying the pressure and temperature conditions suited to an adhesive employed in order to obtain the adhesion.

In one aspect, the first insulating layer 21 is deposited in the form of fibers impregnated with a nonpolymerized resin and subjected, after having been deposited with the appropriate pressure conditions, to a polymerization which simultaneously brings about the curing of the resin, and thus of the first layer, and the adhesion of said first layer to the structure. The polymerization is carried out as a function of the characteristics of the resin. It can, for example, be a polymerization at ambient temperature under the effect of a catalyst of the resin, of a polymerization by application of a thermal curing, of a photopolymerization obtained by application of light radiation, generally ultraviolet radiation, or of all other conditions applicable to the resin and suited to the environment of the structure.

The thickness Ei of the first insulating layer 21 is, for example, between 0.2 mm and 1 mm, a thickness sufficient in comparison with the voltages used, for example, in an aircraft, which corresponds in practice to one or two plies of a fabric of woven glass fibers.

In a second substage 242 of the fourth stage, a second protective and tie layer 22 is deposited on top of the first insulating layer 21.

The second protective and tie layer 22 consists of a metal deposit comprising mainly zinc or aluminum by a flame spraying process.

The flame spraying process is known per se. It consists in bringing a product to be deposited to a melting temperature by the combustion of a mixture of oxygen with a combustible gas in order to form an “oxy-gas” flame and in spraying the molten product at the desired location by a propulsion fluid, for example a compressed gas, such as air or a neutral gas.

In the present case, there has to be formed a thin layer of a material which ensures the protection of the insulating layer and of the structure during the application of the process of deposition of the material of the third conductive layer 23.

In the present case, the first insulating layer 21 is relatively weak and sensitive to thermal attacks and to mechanical attacks.

The flame spraying process is consequently carried out with minimum energy conditions in order not to substantially degrade the first insulating layer 21 on which the second layer 22 is deposited. Thus, zinc or aluminum or alloys using one of these materials as main component, which are not very demanding in energy in order to be brought to a temperature at least of softening, if not of melting, and to be sprayed, is employed.

In practice, other metals or alloys exhibiting similar characteristics can be used to form the second layer. However, they should exhibit a hardness under cold conditions sufficient to withstand the process for the deposition of the third layer and should also observe the constraints related to the environmental specifications for the use anticipated, in particular in terms of toxicity and of flammability.

A temperature of the flame is between 200° C. and 3000° C., preferably between 280° C. and 1100° C., and the material is sprayed with a rate of between 20 m/s and 100 m/s, preferably between 25 m/s and 70 m/s.

The second protective and tie layer is preferably relatively thin, a thickness of between 0.05 mm and 1.5 mm having shown that it is sufficient for the applications under consideration to introduce the desired attaching and protective properties.

The thickness and the width which are desired for this second protective and tie layer 22 are obtained by spray nozzle shapes, by adjusting the parameters of the process, such as the flow rate of the material deposited, and also from an advance of the spray nozzle and the number of passes, if appropriate.

Advantageously, the displacement and the orientation of the nozzle by a robot makes it possible to precisely follow the trajectory corresponding to the line 20 to be produced and to obtain substantially constant characteristics along said line, which result would be difficult to obtain by a manual displacement of the nozzle, even if a manual displacement is not ruled out, in particular in the case of repair procedures.

In a third substage 243 of the fourth stage, a third conductive layer 23 is deposited on top of the second protective and tie layer 22, without substantially extending beyond said second protective and tie layer.

The third layer 23 consists of a metal deposit comprising mainly copper or a copper-based alloy, or aluminum or an aluminum-based alloy, by a cold spraying process.

The cold spraying process is known. It is a metallization process in which metal particles are sprayed at high speed, speeds of greater than 800 m/s being commonly employed in this process, by a pressurized gas onto the piece, the force of impact carrying out the cold soldering of the sprayed metal material under the mechanical effect of the impacts, thus ensuring the quality of the deposit.

The advantages of the cold spraying process are known, in particular good cohesion with the surface subjected to the spraying, a low porosity of the material deposited, a reduced level of oxidation as a result of the moderate temperature to which the metal material is brought, low internal tensions of the deposited material as a result of a limited level of shrinkage for the same reasons of moderate temperature, an accuracy of the deposition on the treated regions which makes it possible to produce relatively fine patterns without employing physical masks.

It also makes it possible to achieve thicknesses of several millimeters while retaining these qualities.

In contrast to the flame spraying process, the cold spraying process, which makes it possible to achieve thicknesses of deposited metal which are compatible with the production of the desired electrically conductive lines, is relatively aggressive mechanically and is liable to damage the insulating material made of glass fibers and polymer matrix of the first layer 21, and the material of the structure, in particular when it is not of metal.

In the process of the disclosed embodiment, the use of this cold spraying process, which makes it possible to produce the third layer 23, is, however, possible by the prior production of the second protective and tie layer 22, which protects the first insulating layer from the direct attack of the cold spraying.

Despite this protective and tie layer, care is taken, for the implementation of this third substage, not to concentrate energy fluxes for an excessive length of time on one and the same region of the structure, and the deposition by cold spraying during this third substage is carried out as much as needed by multiple passes in order to achieve the width and the thickness desired for the third conductive layer.

The conditions of the cold spraying will also be adjusted in order to limit as much as possible the energy flux endured by the second layer 22 and the underlying layers, while guaranteeing the formation of the conductor formed by the sprayed material.

A temperature of the gas is between 100° C. and 1100° C., preferably between 200° C. and 600° C., and a pressure of the gas is between 10 times and 50 times standard atmospheric pressure, preferably between 18 times and 45 times standard atmospheric pressure.

As in the case of the first insulating layer and of the second protective and tie layer, it will be preferred to employ a robot for displacing the cold spraying head and ensuring the accuracy and the homogeneity of the deposition.

The fourth stage 240 is very obviously produced for each of the lines which have to be formed on the face 11 of the structure 10 until the electrical network defined during stages two 220 and three 230 of the process has been created, which stages are a priori carried out before the first stage 210, during the design of the vehicle, and can result in a definition of the electrical network according to the disclosed embodiment common, at least in part, to a family of vehicles of one and the same model.

As already indicated, the process makes it possible to produce lines which intersect on the face 11 of the structure 10, the electrical insulation being produced between a second line 20(b) crossing a first line 20(a), passing over the top of said first line, by the first layer 21(b) of said second line, as illustrated diagrammatically in section in FIG. 4c.

The process, on depositing the successive layers of a line, also makes it possible to follow the more or less complex shapes of the surface of a structure, resulting from shapes of the pieces of the structure or of assemblages of pieces. FIG. 4b illustrates a simplified example of assemblage of two panels of a structure 10 and of a line 20 passing over the two panels by following, in this case, the complex contours of the junction region of said two panels.

When a line is produced, the connection means 25 of said line are placed at the defined locations according to known electrical joining techniques, soldering, cold spraying of the conductive material of the third layer or clamping of lugs or terminals, for example.

Advantageously, for the production of the lines of the electrical network on the structure, there will be carried out, by successive planes when lines intersect, the deposition on the structure of all the first layers 21 of the different lines, then of all the second layers 22, then of all the third layers 23 and finally of all the connecting means 25 and other finishing operations which are judged useful or necessary.

There is thus optimized the use of the means, which are in practice different and specialized for each of the operations carried out, in order to result in a completed line.

In the case of lines which intersect, there will advantageously be defined strata of lines, the lines of one stratum not intersecting one another and intersecting only lines of strata alone onto which they are superimposed; the production by combination of lines as presented above is then carried out stratum by stratum, beginning with the stratum closest to the structure, followed by the strata which are successively piled up.

When a layer of an electrical insulating protection is deposited on the lines produced, advantageously said layer is deposited in finishing when ail the lines have been formed.

It is understood here that an electrical installation in a structure can employ only lines according to the disclosed embodiment or lines according to the disclosed embodiment combined with lines produced according to the known methods and forms using wires, comprising a conductive core and an insulating coating, held by supports themselves attached to the structure.

Lines of the disclosed embodiment and lines on supports can be arranged independently or be mounted in series in order to respond to constraints specific to the electrical installation or to the structure.

The lines of the disclosed embodiment can, in case of need, be repaired in the event of local damage to the third conductive layer 23.

In the case of loss of electrical continuity due to localized damage 37, the line can be repaired by locally reconstructing the third layer by a cold spraying similar to that employed to form the third layer, after having carried out, if need be, a stripping of the damaged part.

The line can also be repaired by soldering, to the third layer of said line, a shunt 38 forming an electrical conductive bridge over the defect found, as in the example of FIG. 4f.

The line can also, in a specific case where the defect has not been located, and in particular while waiting in order to be able to carry out a lasting repair, be duplicated by a line mounted on supports, which solution is similar to the replacement of a line in a bundle of lines mounted on supports.

The disclosed embodiment thus makes it possible to incorporate, on the faces of a structure, electrical conductors, without them being taken substantially in the volumes defined by the structure, arranged in order to constitute a complex network for distribution of electrical energy toward items of equipment and in order to constitute a network for communication of data between items of equipment. The network set up is formed after the production of the structure or of subassemblies of a complex structure and the lines of the network are accessible in case of need when the structure is in service for checking, repair and modification operations.

This possibility is obtained in practice on any type of material constituting the structure and in particular on electrical conductive materials, on electrical insulating materials and on materials comprising a matrix formed with an organic resin.

The disclosed embodiment simplifies the design of the electrical installation of a vehicle and simplifies the production thereof with the effects of decreasing the time necessary for the mounting and for the checks on the electrical installation.

The benefit of the disclosed embodiment also relates to the reduction in the weight owing to the fact that the normal excessive lengths are avoided and that the conductive sections can be simply adapted for each segment of a line.

The principle of the lines of the disclosed embodiment also excludes the phenomenon of arc propagation which is encountered between neighboring electrical cables brought into contact and separated by an insulator of the conductor.

The principles of the disclosed embodiment also prevent the phenomena of wear of the insulators of electrical cables when said cables rub over the structure.

What is claimed is:

1. An assembly comprising a structure and at least one electrical line on a face of said structure, an electrical conductive layer of said electrical line resulting from a deposition of an electrical conductive material, between ends of said line, on said face, by a cold spraying process, wherein the line comprises a protective and tie layer resulting from the deposition of a material by oxy-gas flame spraying on which is deposited the electrical conductive material by the cold spraying process, the material of said protective and tie layer being sprayed in order to form a continuous protective screen between the structure and the cold-sprayed material.

2. The assembly as claimed in claim 1, wherein the protective and tie layer comprises mainly zinc, or a zinc-based alloy, or aluminum, or an aluminum-based alloy.

3. The assembly as claimed in claim 1, wherein the protective and tie layer exhibits a thickness of between 0.05 mm and 1.5 mm.

4. The assembly as claimed in claim 1, wherein an insulating layer of an electrical insulating material is interposed between the structure and the protective and tie layer, a width of said insulating layer being greater than a width of said protective and tie layer.

5. The assembly as claimed in claim 4, wherein the insulating layer comprises at least one ply of glass fibers which are held in a cured matrix of an organic polymer.

6. The assembly as claimed in claim 4, wherein a thickness Eᵢ of the insulating layer is between 0.2 mm and 1 mm.

7. The assembly as claimed in claim 1, wherein the electrical conductive layer mainly comprises copper, or a copper-based alloy, or aluminum, or an aluminum-based alloy.

8. The assembly as claimed in claim 1, wherein the electrical line comprises means for electrical connection to items of equipment.

9. The assembly as claimed in claim 1, comprising a plurality of electrical lines in which at least one upper line crosses at least one lower line, said at least one lower line being locally between the structure and said at least one upper line, said at least one upper line comprising an insulating layer at least where the lines intersect.

10. The assembly as claimed in claim 1, wherein the structure is made of a metal material and/or of a composite material comprising organic or inorganic fibers held in a cured organic matrix.

11. A process for producing an electrical line on a surface of a face of a structure, said process comprising the formation of an electrical conductive layer, of said electrical line, resulting from a deposition by a cold spraying process of an electrical conductive material, between ends of said line, on said face of the structure, wherein it comprises a stage of oxy-gas flame spraying of a protective material in order to form a protective and tie layer, followed by a stage of cold spraying of the electrical conductive material of the conductive layer on said protective and tie layer.

12. The process as claimed in claim 11, further comprising a stage of deposition, on the structure, of an electrical insulating layer on which is produced the protective and tie layer by oxy-gas flame spraying of the protective material.

13. The process as claimed in claim 12, wherein the insulating layer is made of at least one ply of a fabric of glass fibers or of fibers of an electrically insulating polymer which are held in a matrix of an organic polymer and attached to the structure.

14. The process as claimed in claim 11, wherein the material sprayed by the oxy-gas flame spraying process in order to form the protective and tie layer mainly comprises zinc, or a zinc-based alloy, or aluminum, or an aluminum-based alloy.

15. The process as claimed in claim 14, wherein the protective and tie layer is formed with a thickness of between 0.05 mm and 1.5 mm.

16. The process as claimed in claim 14, wherein, during the stage of producing the protective and tie layer, a temperature of the flame is between 200° C. and 3000° C., preferably between 280° C. and 1100° C., and the material is sprayed with a rate of between 20 m/s and 100 m/s, preferably between 25 m/s and 70 m/s.

17. The process as claimed in claim 11, wherein the material cold-sprayed in order to form the electrical conductive layer mainly comprises copper, or a copper-based alloy, or aluminum, or an aluminum-based alloy.

18. The process as claimed in claim 17, wherein the cold spraying of the sprayed material is carried out with a temperature of the gas of between 100° C. and 1100° C., preferably between 200° C. and 600° C., and a pressure of the gas of between 10 times and 50 times standard atmospheric pressure, preferably between 18 times and 45 times standard atmospheric pressure.

19. A process for producing an assembly comprising a structure and at least one electrical line on a face of said structure, the process comprising a stage of producing the structure, a stage of definition of the position of means of connection to said at least one line and of definition of the expected performance levels of said at least one line, a stage of definition of the physical characteristics of said at least one line, and then a stage of producing the at least one line as claimed in the process of claim 11.
